(19) United States
(12) Patent Application Publication
(10) Pub. No.: US 2025/0022882 A1
(43) Pub. Date: Jan. 16, 2025

(54) TRANSISTOR WITH TRENCH ISOLATED WELL FOR SEMICONDUCTOR DEVICE ASSEMBLIES

(71) Applicant: Micron Technology, Inc., Boise, ID (US)

(72) Inventors: Martin W. Popp, Boise, ID (US); Zia A. Shafi, Boise, ID (US)

(21) Appl. No.: 18/768,932

(22) Filed: Jul. 10, 2024

Related U.S. Application Data
(60) Provisional application No. 63/526,267, filed on Jul. 12, 2023.

(51) Int. Cl. H01L 27/12; H01L 21/762; H01L 21/84

(52) U.S. Cl. CPC H01L 27/1203; H01L 21/76251; H01L 21/84

(57) ABSTRACT

A semiconductor device including a complementary metal-oxide-semiconductor (CMOS) device that includes a P-Well region including a P-Well, a first shallow trench isolation (STI) region that is disposed on a frontside surface of the CMOS device and above the P-Well, and a first deep trench isolation (DTI) region that is disposed under the first STI region and that extends to a backside surface of the CMOS device, the first DTI region completely surrounding the P-Well, and a N-Well region adjacent to the P-Well region, the N-Well region including a N-Well, a second STI region disposed on the frontside surface of the CMOS device and above the N-Well, and a second DTI region that is disposed under the second STI region and that extends to the backside of the CMOS device, the second DTI region completely surrounding the N-Well; and a secondary device bonded to the CMOS device.

### CROSS-REFERENCE TO RELATED APPLICATION(S)

The present application claims priority to U.S. Provisional Patent Application No. 63/526,267, filed Jul. 12, 2023, the disclosure of which is incorporated herein by reference in its entirety.

### TECHNICAL FIELD

The present disclosure generally relates to semiconductor devices, and more particularly relates to forming transistor with trench isolated well for wafer to wafer bonding in semiconductor device assemblies.

### BACKGROUND

Fabrication of advanced semiconductor devices such as high-density memory devices generally includes bonding a wafer, e.g., a complementary metal-oxide-semiconductor (CMOS) wafer, to a secondary wafer so as to form a wafer-on-wafer (WOW) packaging. The CMOS wafer usually includes electronic circuits consist of field effect transistors (FETs) to provides control on the semiconductor devices. In the FETs, the source, drain, and channel regions are located on a surface of the CMOS wafer. These regions as well as other functional regions are separated by shallow trench isolation (STI) regions filled by thin dielectric layers. Moreover, for advanced technology nodes, the FETs on the CMOS wafer includes much deeper trenches that are filled by thick dielectric layers and that extend below the transistor active regions in order to prevent leakage currents between adjacent transistor cell units and other undesirable effects. On the other hand, the secondary wafer may include memory arrays including NAND flash memory arrays, dynamic random-access memory (DRAM) arrays, and/or phase change memory (PCM) arrays, the memory arrays being connected to the electronic circuits of the CMOS wafer for data signal and control signal transition. Conventional technologies including direct bonding and fusion bonding can be used to bond the CMOS wafer and one or more memory array wafers to form the semiconductor device assemblies.

### BRIEF DESCRIPTION OF THE DRAWINGS

FIG. 1 depicts a schematic view of a semiconductor device in accordance with embodiments of the present technology.

FIG. 2 depicts a plan-view of the semiconductor device illustrated in FIG. 1 according to embodiments of the present technology.

FIG. 3 depicts a plan-view of another semiconductor device in accordance with embodiments of the present technology.

FIGS. 4A and 4B depict a schematic view and a plan-view of a semiconductor device including through wafer interconnects, respectively in accordance with embodiments of the present technology.

FIGS. 5A through 5D illustrate schematic views of a first flow of processing a semiconductor device including through wafer interconnects according to embodiments of the present technology.

FIGS. 6A through 6E illustrate schematic views of a second flow of processing the semiconductor device including through wafer interconnects according to embodiments of the present technology.

FIGS. 7A through 7E illustrate schematic views of a third flow of processing the semiconductor device including through wafer interconnects according to embodiments of the present technology.

FIG. 8 is a flow chart illustrating a method of processing a semiconductor device including through wafer interconnects according to embodiments of the present technology.

FIG. 9 is a flow chart illustrating a method of processing through wafer interconnects of a semiconductor device, in accordance with embodiments of the present technology.

FIG. 10 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

The fabrication of CMOS transistor devices for advanced semiconductor device assemblies includes formation of N-well and P-WELL regions. In FETs design, the N-well and P-WELL regions are fabricated to form PFET and NFET devices, respectively. In particular, the N-well is doped with a high concentration of N-type impurities and is surrounded by P-type substrate material. It is configured to create P-channel MOS transistors, specifically create a depletion region between PFET source and drain regions. Similarly, the P-well region is doped with a high concentration of P-type impurities and is surrounded by N-type substrate material. It is configured to create N-channel MOS transistors, specifically to create a depletion region between NFET source and drain regions. In general, the fabrication of CMOS transistor devices also includes a complex triple well process that involves a creation of a third deep well region that has a higher doping level to and is disposed under the N-well and P-well regions. The triple-well regions structure is configured to provide electrical isolation between different transistors or other components that are integrated on the same CMOS wafer/die, and to prevent electrical leakage and cross-talk between the transistors. In advanced semiconductor assemblies, however, the CMOS wafer need to be thinned before being stacked on secondary wafers, therefore causing challenges to ion implanting the deep well region in a thinned CMOS wafer substrate. A CMOS device without the triple-well regions may have issues including N-well to P-well leakage through the pristine silicon substrate and latch-up risk caused by parasitic effects between the P-well, N-well, and the substrate.

To address the above-described challenges and others, the present technology includes fully trench isolated FETs in the CMOS wafer for wafer to wafer bonding in the semiconductor device assembly. Particularly, the CMOS wafer is thinned from its backside surface to expose deep trench isolation (DTI) regions embedded therein. In the present technology, the CMOS wafer and a secondary wafer are bonded together by fusion bonding through a dielectric layer disposed at the interface. In the formed semiconductor device, the well regions are completely surrounded by corresponding DTI regions. Further, each of the FETs is isolated by the DTI regions and the interface dielectric layer so as to eliminate leakage current between neighboring well regions. The CMOS device included in the semiconductor device fabricated using the present technology also includes a dedicated TAP cell in each corresponding well region to prevent latch-up risks. In the present technology, a complex triple well isolation process can be further avoided to assist reducing a thickness of the CMOS device for a higher semiconductor device packaging density. The full dielectric isolation of the well regions in the present technology has more advantages of area scaling over triple well isolation scheme, because vertical trenches of DTI regions can be much narrower in comparison to a deeper well implantation.

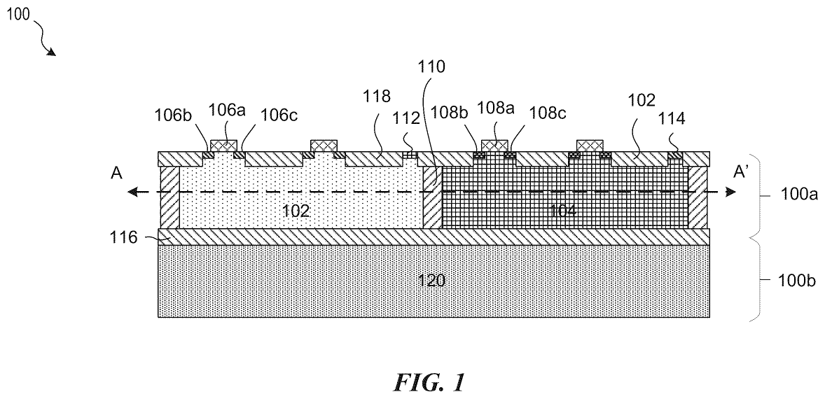

FIG. 1 depicts a cross-sectional schematic view of a semiconductor device 100 in accordance with embodiments of the present technology. As shown, the semiconductor device 100 includes a CMOS device 100a and a secondary device 100b that are bonded by a dielectric layer 116. Specifically, the CMOS device 100a includes NFET devices 106 and PFET devices 108 disposed in P-well region 102 and N-well region 104, respectively.

The semiconductor device 100 comprises one or more NFET 106 disposed on a frontside surface of the substrate. As shown, each NFET 106 includes a gate 106a, a source region 106b, and a drain region 106c, all of which being embedded in the P-well region 102. In some embodiments, the gate 106a may be formed of polysilicon or conductive metals. There may be a gate dielectric layer disposed below the gate 106a and made of gate oxide, silicon dioxide, and/or silico nitride. The source and drain regions 106a and 106c are formed within the substrate and may be heavily doped by a N-type dopant. In addition, the P-well region 102 is doped by a P-type dopant (e.g., doped with Boron and/or Gallium). Generally, the source region 106b and the drain region 106c have higher concentration of dopants than the P-well region 102. Further, the region embedded in the P-well region 102 and is directly below the gate 106a and between the source region 106b and the drain region 106c is referred as a channel of the NFET 106. In some embodiments, the P-well region 102 also includes a PTAP cell 112 that may be disposed at the frontside surface of the substrate and in parallel to the NFETs 106. The PTAP cell 112 is configured to prevent latch-up issue in the CMOS device design by connecting the P-well region 102 to a V_{DD} terminal. In this example, the one or more NFET 106, the PTAP cell 112, and any other components disposed on the frontside surface of the substrate can be isolated by a shallow trench isolation (STI) 118. The STI 118 can be made of dielectric materials to provide better isolation/prevent cross-talk between electrical devices disposed on the frontside surface of the substrate. The STI 118 can be made of materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof.

In addition, the semiconductor device 100 comprises one or more PFET 108 disposed on a frontside surface of the substrate. As shown, each PFET 108 includes a gate 108a, a source region 108b, and a drain region 108c, all of which being embedded in the N-well region 104. In some embodiments, the gate 108a may be formed of polysilicon or conductive metals. There may be a gate dielectric layer disposed below the gate 108a and made of gate oxide, silicon dioxide, and/or silico nitride. The source and drain regions 108a and 108c are formed within the substrate and may be heavily doped by a P-type dopant. In addition, the N-well region 104 is doped by a N-type dopant (e.g., doped with Phosphorus, Arsenic, and/or Antimony). Generally, the source region 108b and the drain region 108c have higher concentration of dopants than the N-well region 104. Further, the region embedded in the N-well region 104 and is directly below the gate 108a and between the source region 108b and the drain region 108c is referred as a channel of the PFET 108. In some embodiments, the N-well region 104 also includes a NTAP cell 114 that may be disposed at the frontside surface of the substrate and in parallel to the PFETs 108. The NTAP cell 114 is configured to prevent latch-up issue in the CMOS device design by connecting the N-well region 104 to a V_{DD} terminal. In this example, the one or more PFET 108, the NTAP cell 114, and any other components disposed on the frontside surface of the substrate can be isolated by the STI 118.

In some embodiments, the CMOS device 100a may also include a substrate bias voltage contract (not shown) in each of the P-well and N-well regions. For example, a first dedicated bias voltage contract may be formed on the frontside surface of the substrate and connected to the P-well region 102. Similarly, a second dedicated bias voltage contract may be formed on the frontside surface of the substrate and connected to the N-well region 104. This configuration enables to bias the P-well region of the NFET devices and the N-well region of the PFET devices independently to improve the overall performance of the CMOS device 100a.

As shown in FIG. 1, the CMOS device 100a may be thinned from its back side and then its P-well region 102 can bonded to the secondary device 100b, through the dielectric layer 116. During the semiconductor device assembly, the substrate of the CMOS wafer can be thinned to expose the P-well region 102 and then bonded to a secondary wafer for the W2W bonding. In this embodiment, the CMOS device 100a may have a thickness ranging from 0.5 μm to 5 μm.

The CMOS device 100a also include DTI regions 110 that completely surround corresponding P-well or N-well regions. As shown, each of the DTI regions 110 is disposed under a corresponding STI region 118 and vertically extends to a backside surface of the CMOS device 100a. The DTI regions may have a thickness ranging from 0.5 μm to 5 μm and a width ranging from 1 μm to 10 μm. In this example, the DTI regions 110 are configured to electrically isolate the P-well regions and N-well regions included in the CMOS device 100a. More specifically, the DTI regions 110 can provide superior electrical isolation compared to STI and other isolation techniques because it creates a thicker and more robust insulating layer between the active regions of adjacent devices. In this example, the DTI regions 110 can be used to reduce parasitic capacitance and leakage currents between adjacent P-well and N-well regions, without forming an additional deeper third type well region through a complex triple well technique.

In the present disclosure, the secondary device 100b can be coupled to the backside surface of the CMOS device 100a, e.g., the CMOS device 100a and the secondary device 100b can be bonded together. The secondary device 100b may include memory arrays including NAND flash memory arrays, dynamic random-access memory (DRAM) arrays, and/or phase change memory (PCM) arrays, the memory arrays being connected to electrical circuits of the CMOS device 100a for data signal and control signal transition. In this example, the backside surface of the CMOS device 100a and a frontside surface of the secondary device 100b are bonded through the dielectric layer 116. Here, the dielectric layer 116 provides electric isolation among the components included in each of the CMOS device 100a and the secondary device 100b. Further, it may be a direct bonding interface with fusion bonds formed between CMOS device 100a and the secondary device 100b, which can be formed by attaching dielectric layers of the CMOS device 100a and secondary device 100b and applying heat or compressive pressures there between. The dielectric layer 116 may be made of insulating materials including silicon oxide and silicon nitride.

In some other embodiments, the CMOS device 100a and the secondary device 100b may be stacked on additional devices in the semiconductor device assembly. For example, additional memory devices may be bonded to a backside surface of the secondary device 100b to form a multiple stack memory device assembly. Further, the CMOS device 100a may be directly bonded to the secondary device 100b using a direct bonding technique. For example, the backside surface of the CMOS device 100a can be directly bonded to the front side of the secondary device 100b to form silicon-silicon covalent bonds through applying pressure and/or heat. In this example, the dielectric layer 116 may not be needed for the bonding.

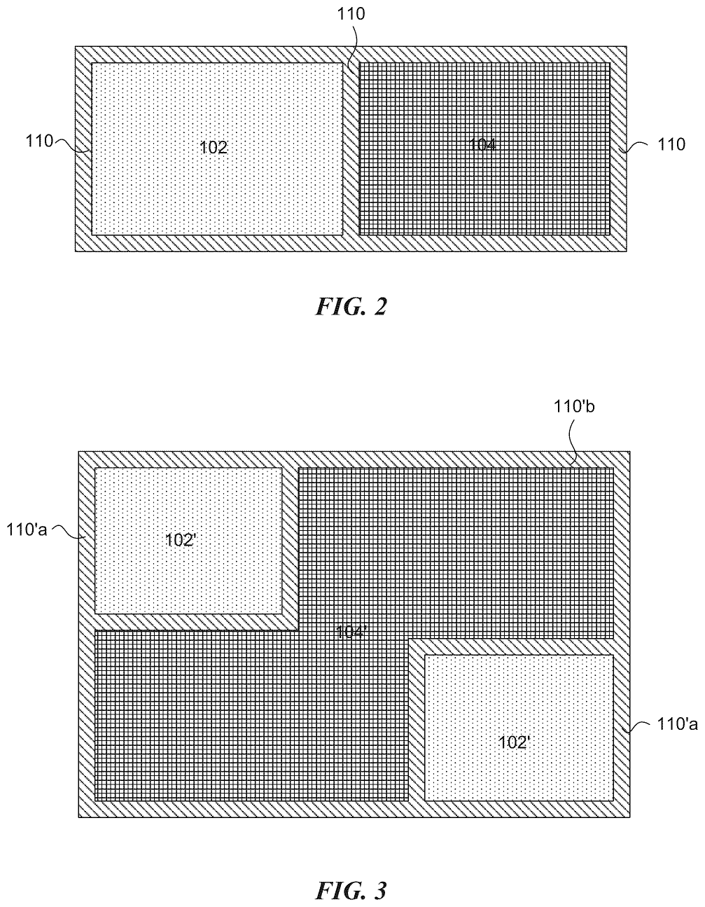

FIG. 2 depicts a plan-view of the CMOS device 100a of the semiconductor device 100 along the A-A′ plane as shown in FIG. 1, according to embodiments of the present technology. As described, the CMOS device 100a of the semiconductor device 100 may include the P-well region 102 and the N-well region 104 that are disposed next to each other. The shape and location of each of the P-well region 102 and the N-well region 104 on the CMOS device 100a may depend on the transistor floor plan and photolithography process limitations. In this example, each of the P-well region 102 and the N-well region 104 has a rectangular shape on the horizontal plane and includes one edge that are parallelly aligned. Specifically, each of the P-well region 102 and the N-well region 104 are completely surrounded by the DTI 110. In this example, the P-well region 102 and the N-well region 104 are adjacent and share one common edge of the DTI 110, as shown in the middle of FIG. 2. In some other embodiments, the P-well region 102 and the N-well region 104 may be away from each other (e.g., having a distance between their closed edges longer than the width of the DTI), each being completely surrounded by a dedicated DTI for electrical isolation. In some other embodiments, the P-well region 102 and the N-well region 104 may each has a circular shape or a polygon shape. They may not have edges that are parallelly aligned and are surrounded by dedicated DTIs separately. As described to FIG. 1, the DTI 110 are disposed below the STI 118 and extends all the way to the backside surface of the CMOS device 110a, which enables a completely electrical isolation between the adjacent well regions of the CMOS device 100a.

FIG. 3 depicts a plan-view of another CMOS device 100a′ that may be bonded on the secondary device for WOW bonding in advanced semiconductor device assembly, according to embodiments of the present technology. In this example, P-well regions 102′ and a N-well region 104′ do not have similar dimensions. Particularly, each of the P-well regions 102′ and a N-well region 104′ is completely surrounded by DTI regions 110′a and 110′b, respectively. Due to the floorplan of the well regions in the CMOS device 100a′, two edges of the DTI 110′a are shared between the P-well regions 102′ and N-well region 104′. In this example, each of the adjacent well regions are electrically isolated by corresponding DTI to prevent leakage current there between.

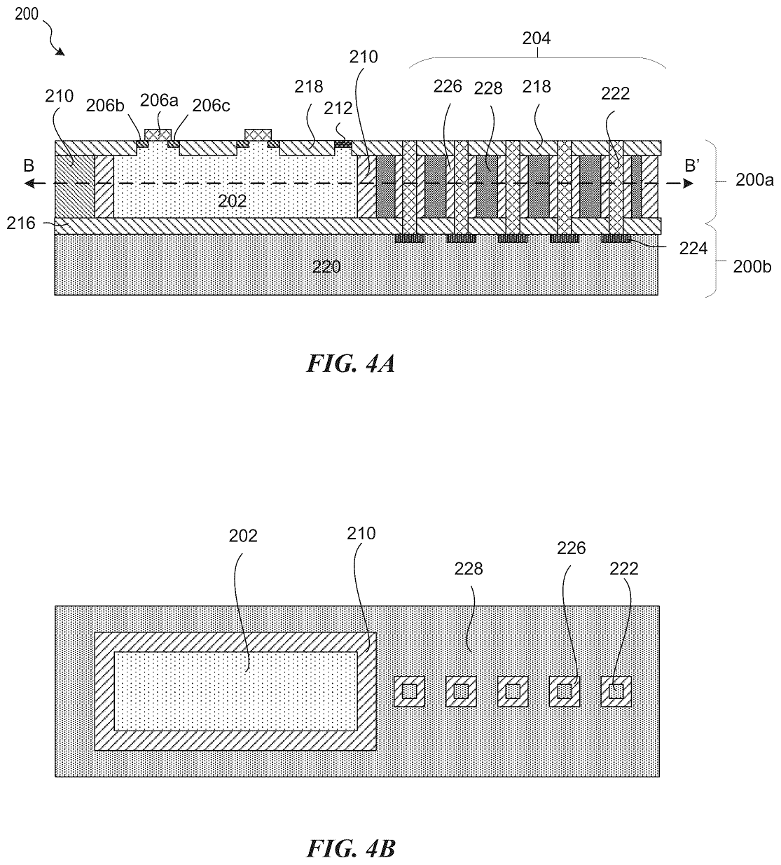

Now turning to FIGS. 4A and 4B which respectively depict a cross-sectional schematic view and a plan-view of a semiconductor device 200 including through wafer interconnects 222, in accordance with embodiments of the present technology. In this example, the semiconductor device 200 includes a CMOS device 200a and a secondary device 200b that are bonded together in the semiconductor device assembly. Specifically, the CMOS device 200a includes a well region 202 and interconnect region 204 through which through wafer interconnects 222 pass and connects to the secondary device 220.

As shown in FIG. 4A, one or more FETs 206 can be disposed on a frontside surface of the CMOS device 200a. Each of the FETs 206 includes a gate 206a, a source 206b and a drain 206c. In addition, each of the well region 202 may include a TAP cell 212 that is disposed on the frontside surface of the CMOS device 200a. In this example, the one or more FETs 206, the TAP cell 212, and any other electrical components can be electrically separated by a STI 218. In this CMOS device 100a, the well region 202 is completed surrounded by a DTI region 210 for electrical isolation. In particular, the DTI 210 is disposed under corresponding STI 218 and extends to a backside surface of the CMOS device 200a. In some embodiments and as shown in FIG. 4B, the well region 202 can have a rectangular shape and the DTI 210 are disposed outside four edges of the well region 202, so as to isolate well region 202 to adjacent well regions and the interconnect region 204 and prevent leakage current therebetween.

In this example, the well region 202 and the interconnect region 204 can be separated by STI region 218 and DTI region 210. As shown in FIGS. 4A and 4B, additional DTI regions 226 can be formed in the interconnect region 204 and separated by the substrate material 228. For example, each of the DTI regions 226 can be formed in a rectangular shape in the horizontal plane and under the corresponding STI region 218. Similar to the DTI 210, each of the additional DTI regions extends all the way to the backside surface of the CMOS device 200a and is in contact to a dielectric layer 216 disposed at the interface of the CMOS device 200a and the secondary device 200b. Each of the additional DTI regions 226 may have a diameter or a width ranging from 1 μm to 50 μm.

Further, the secondary device 200b of the semiconductor device 200 may include memory arrays including NAND flash memory arrays, DRAM arrays, and/or PCM arrays, the memory arrays being connected to electrical circuits of the CMOS device 200a, through the through wafer interconnects 222, for data signal and control signal transition. As shown in FIGS. 4A and 4B, each of the through wafer interconnects 222 passes through the STI region 218, the corresponding one of additional DTI regions 226, and the dielectric layer 216. Each of the through wafer interconnects 222 is further connected to corresponding landing pad of the secondary device 200b. In this example, each of the through wafer interconnects 222 may be made of electrically conductive materials including metals such as cooper, tungsten, gold, nickel, aluminum, silver, or metal alloys. Further, each of the through wafer interconnects may have a width ranging from 0.5 μm to 20 μm and a length ranging from 0.5 μm to 10 μm. As shown in FIG. 4B, each of the through wafer interconnects 222 are processed to pass through the corresponding additional DTI regions 226. Moreover, each of the through wafer interconnects 222 is electrically isolated by the corresponding additional DTI regions 226 from the substrate material 228. In this example, the through wafer interconnects 222 can be configured to transfer data signal and control signal between the electrical devices of CMOS device 220a and memory arrays of the secondary device 200b.

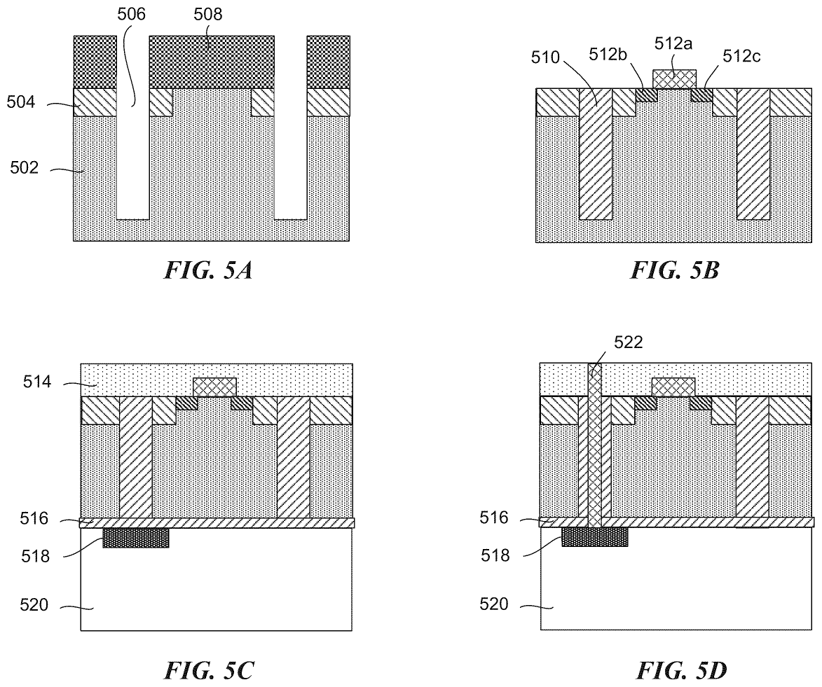

FIGS. 5A through 5D illustrate cross-sectional schematic views of a first flow 500 of processing a semiconductor device including through wafer interconnects according to embodiments of the present technology. In this example, STI regions 504 are fabricated prior to processing of DTI regions 510 on a CMOS wafer 502. As shown in FIG. 5A, the STI regions 504 can be processing on a frontside surface of the CMOS wafer 502 through etching shallow trenches and filling with dielectric materials. The STI regions 504 can be further planarized by a chemical-mechanical polishing (CMP) technique. In this region, the STI regions 504 may have a thickness ranging from 100 nm to 500 nm and made of materials including silicon oxide, silicon nitride, and/or silicon oxynitride. A hard mask layer 508 can be coated about the frontside surface of the CMOS wafer 502, once the STI regions 504 are completed. The hard mask layer 508 may made of silicon nitride or carbon, and be patterned to form openings above corresponding STI regions 504. An etching process can be involved, such as a reactive ion etching process (RIE), to etch deep trenches 506 through the harm mask openings and into the substrate of CMOS wafer 502. The deep trenches 506 may have a width ranges from 1 μm to 50 μm and a thickness ranges from 1 μm to 100 μm.

After forming the deep trenches 506, as shown in FIG. 5B, dielectric materials can be filled into the deep trenches 506 to form DTIs 510. In this example, the DTI 510 may be made of dielectric materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Here, a thin film deposition process including chemical vapor deposition (CVD), physical vapor deposition (PVD), or spin coating techniques can be involved to fill dielectric material into the deep trenches 506. The CMP process may be also involved to planarize a top surface of the DTI 510. As shown in FIG. 5B, FETs 512 including a gate 512a, a source 512b, and a drain 512c can be formed on the frontside surface of the CMOS wafer 502. Specifically, the FETs 512 are disposed within a well region that is isolated by adjacent DTIs 510.

In a next step shown in FIG. 5C, a hard mask layer 514 can be deposited above the frontside surface of the CMOS wafer 502 to cover the FETs 512 for mechanical support. Next, the CMOS wafer 502 can be thinned from its backside using a mechanical grinding process or polishing process. In this example, the thinned CMOS wafer 502 may have a thickness ranging from 0.5 μm to 5 μm. Here, the CMOS wafer 502 can be thinned from its backside surface until exposing the DTI regions 510. Following the wafer backside thinning, a first dielectric layer can be deposited on the backside surface of thinned CMOS wafer 502. The first dielectric layer may be made of silicon oxide or silicon nitride. As shown in FIG. 5C, the DTI regions 510 and the dielectric layer 516 completely isolates the well region in which the FET 512 is disposed from adjacent well regions to prevent leakage current. Further, a secondary wafer 520 can be introduced to the process. Particularly, a second dielectric layer having a same material to the first dielectric layer can be deposited above a frontside surface of the secondary wafer 520. In this example, the secondary wafer 520 may include NAND flash memory arrays, DRAM arrays, and/or PCM arrays. Moreover, a plurality of landing islands may be disposed in the secondary wafer 520 and above its frontside surface.

In this step, the thinned CMOS wafer 502 and the secondary wafer 520 can be bonded together through a direct bonding technique. For example, the first dielectric layer of the CMOS wafer 502 and the secondary dielectric layer of the secondary wafer 520 can be aligned and pressed together to form fusion bonds therebetween. The bonded first and secondary dielectric layers may form the dielectric layer 516. In this process, pressure and thermal annealing may be applied at the bonding interface to encourage formation of covalent bonds between the first and second dielectric layers to enhance the bonding interface.

In a next step and as shown in FIG. 5D, a lithography patterning process can be applied on the hard mask layer 514 to for openings above corresponding DTIs 510. After that, a high-aspect ratio etching process such as RIE process can be conducted through the openings of hard mask layer 514, to etch a hole through the corresponding DTI 510. This process is continued to etch through the dielectric layer 516 and stops at corresponding landing pad 518. In addition, electrically conductive materials including metals such as cooper, tungsten, gold, nickel, aluminum, silver, or metal alloys can be filled into the hole to form the through wafer interconnects 522. In this example, the first flow 500 of processing the semiconductor device may also involves dicing to cutting the bonding CMOS wafer 502 and the secondary wafer 520 into individual chips using a diamond saw or laser. Further, a molding process may be conducted to package the diced CMOS device and secondary device in a protective case to protect the semiconductor device from damage and to facilitate handling and mounting.

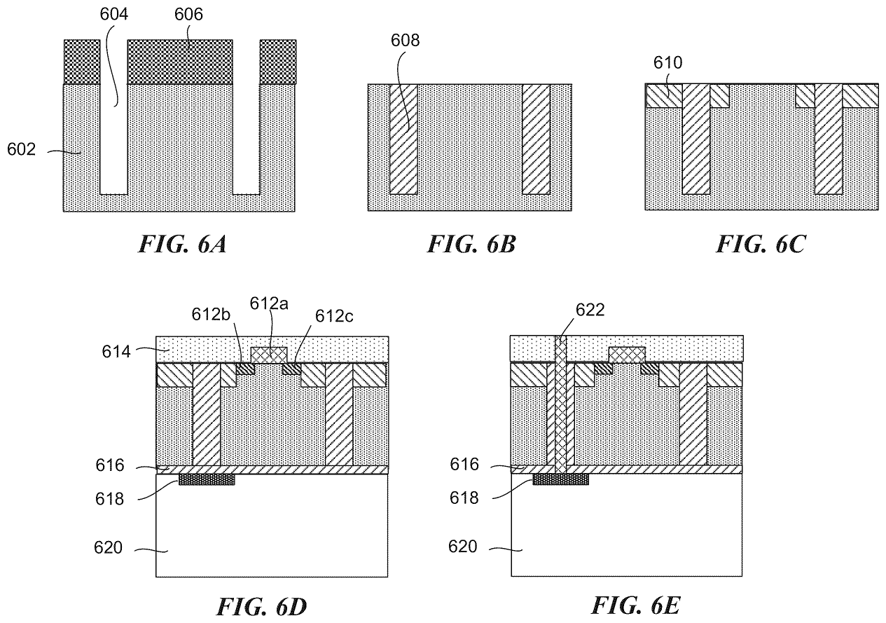

Turning to FIGS. 6A through 6E which illustrate cross-sectional schematic views of a second flow 600 for processing a semiconductor device including through wafer interconnects according to embodiments of the present technology. In this flow, DTI regions 608 are fabricated prior to the processing of STI regions 610. As shown in FIG. 6A, a hard mask layer 606 can be patterned above a frontside surface of a CMOS wafer 602. An etching process such as RIE can be conducted through the patterned hard mask layer 606 and into the substrate of CMOS wafer 602 to form deep trenches 604. In this example, the deep trenches 604 may have a width ranges from 1 μm to 50 μm and a thickness ranges from 1 μm to 100 μm. After the formation of deep trenches 604, dielectric materials can be filled into to form DTI regions 608, as shown in FIG. 6B. The CMP process may be used to remove the hard mask layer 606 and planarize a top surface of the DTI regions 608.

In a next step and as shown in FIG. 6C, another hard mask layer (not shown) may be patterned on the frontside surface of the CMOS wafer 602. An etching process such as RIE can be used again to etch shallow trenches, through the patterned another hard mask layer, on the CMOS wafer 602. Dielectric materials such as silicon oxide or silicon nitride can be filled into the shallow trenches to from the STI regions 610. Here, the CMP process may be conducted again to remove the another hard mask layer and planarize a top surface of the STI regions 610.

Similar to the procedures described on FIGS. 5C and 5D, the CMOS wafer 602 can be bonded to another secondary wafer 620 and having through wafer interconnects 622 formed therebetween. For example, one or more FET 612 including a gate 612a, a source 612b, and a drain 612c can be formed on a top surface of the CMOS wafer 602. The FET 612 as well as other electrical components can be embedded in a well region isolated by the DTI regions 608. Further, the CMOS wafer 602 can be thinned from its backside surface using a mechanical grinding or polishing process. A third dielectric layer can be deposited on the backside surface of thinned CMOS wafer 602. As shown in FIG. 6D, the secondary wafer having a fourth dielectric layer coated there on can be introduced to the process. The CMOS wafer 602 and the secondary wafer 620 can be bonded through aligning the third and fourth dielectric layers and applying pressure and heat there on. As shown, a dielectric layer 616 having fusing bonds can be formed at the interface of CMOS wafer 602 and the secondary wafer 620.

After the wafer to wafer bonding, a photolithography patterning process can be conducted on a hard mask layer 614, to form a hole that passes through the hard mask layer 614, the corresponding DTI region 608, and the dielectric layer 616. Electrically conductive materials including metals such as cooper, tungsten, gold, nickel, aluminum, silver, or metal alloys can be filled into the hole to form the through wafer interconnects 622. As shown in FIG. 6E, the through wafer interconnects 622 pass through the CMOS wafer 602 and are connected to corresponding landing pads of the secondary wafer 620, respectively.

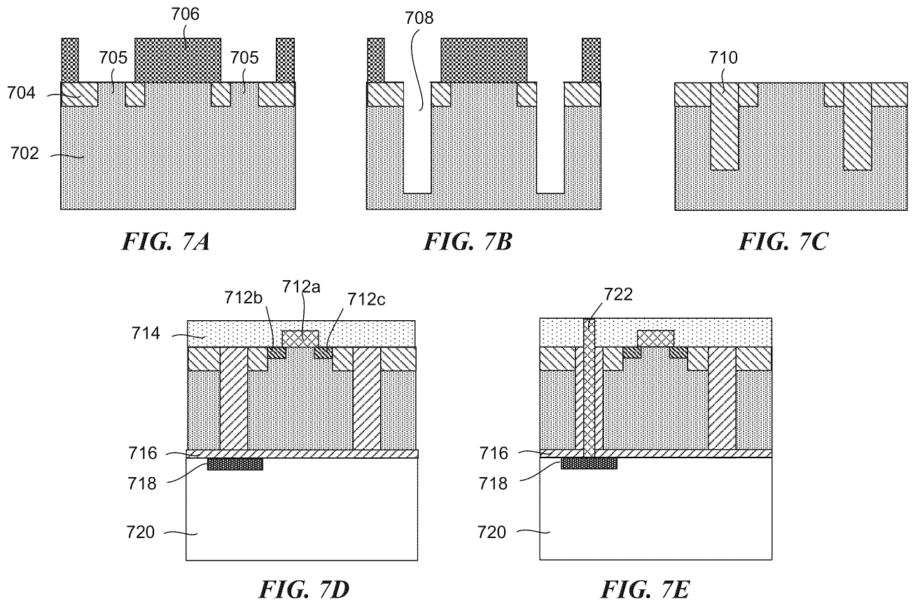

In some other embodiments, the DTI regions can be fabricated in a self-aligned process after the formation of STI regions. For example, FIGS. 7A through 7E illustrate cross-sectional schematic views of a third flow 700 for processing a semiconductor device including through wafer interconnects according to embodiments of the present technology. In this flow 700, STI regions 704 can be first formed through patterning a first hard mask layer (not shown), etching through patterned hard mask layer into substrate of the CMOS wafer 702, and filling with dielectric materials such as silicon oxide or silicon nitride. This flow 700 continues to form another hard mask layer 706 above the front side surface of the CMOS wafer 702. Another lithography patterning process can be performed to form openings in the hard mask layer 706 to expose corresponding substrate regions 705 of the CMOS wafer 702, the exposed substrate being disposed between neighboring STI regions 704. As shown in FIG. 7A, the openings of the hard mask layer 706 may be wider than the corresponding exposed substrate region 705.

The DTI regions 710 can be formed through a self-aligned etching process, which can be a directional etching technique and etches the substrate material selective to the hard mask 706 and STI regions 704. For example, a directional RIE etch process can be used to vertically etch a silicon of the CMOS wafer 702 substrate to form deep trenches 708. The RIE process may be selective to a carbon content of the hard mask layer 706 and dielectric materials of the STI regions 704. Thereafter, as shown in FIG. 7C, dielectric materials such as silicon oxide or silicon nitride can be filled into the deep trenches 708 to form DTI regions 710. The CMP process may be used here to remove the hard mask layer 706 and planarize a top surface of the DTI regions 710. As shown in FIGS. 7D and 7E, the CMOS wafer 702 can be further bonded to another secondary wafer 720 and having through wafer interconnects 722 formed therebetween, similar to the procedures described on FIGS. 5C and 5D. For example, one or more FET 712 including a gate 712a, a source 712b and a drain 712c can be formed on a top surface of the CMOS wafer 702. The FET 712 as well as other electrical components can be embedded in a well region isolated by the DTI regions 704. Further, the CMOS wafer 702 can be thinned from its backside surface using a mechanical grinding or polishing process. A fifth dielectric layer can be deposited on the backside surface of thinned CMOS wafer 702. As shown in FIG. 7D, the secondary wafer 720 having a sixth dielectric layer coated thereon can be introduced to the flow 700. The CMOS wafer 702 and the secondary wafer 720 can be bonded through aligning the fifth and sixth dielectric layers and applying pressure and heat there on. As shown, a dielectric layer 716 having fusing bonds can be formed at the interface of CMOS wafer 702 and the secondary wafer 720.

After the wafer to wafer bonding process, a photolithography patterning process can be conducted on a hard mask layer 714, to form a hole that passes through the hard mask layer 714, the corresponding DTI region 710, and the dielectric layer 716. Electrically conductive materials including metals such as cooper, tungsten, gold, nickel, aluminum, silver, or metal alloys can be filled into the hole to form the through wafer interconnects 722. As shown in FIG. 7E, the through wafer interconnects 722 pass through the CMOS wafer 702 and are connected to corresponding landing pads of the secondary wafer 720, respectively.

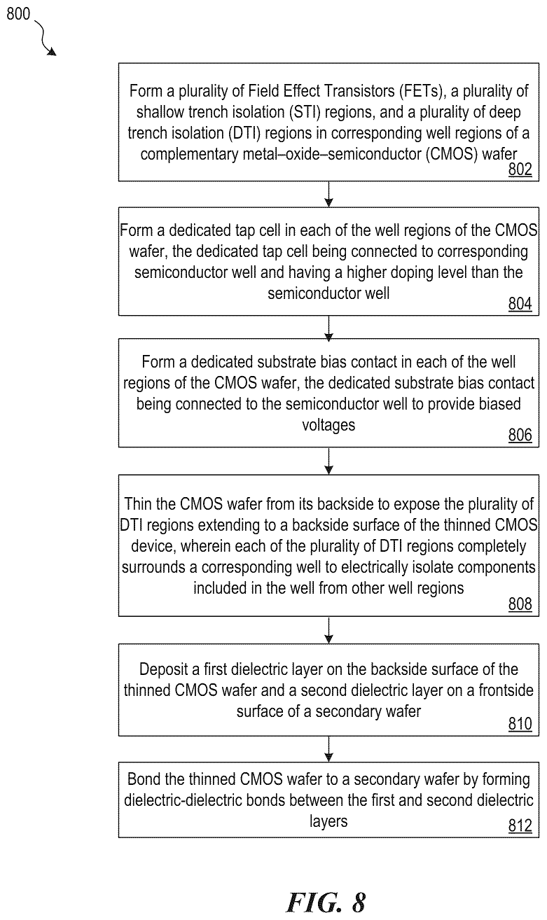

FIG. 8 is a flow chart illustrating a method 800 for processing a semiconductor device including through wafer interconnects according to embodiments of the present technology. For example, the method 800 includes forming a plurality of FETs, a plurality of STI regions, and a plurality of deep trench isolation DTI regions in corresponding well regions of a CMOS wafer, at 802. For example, the FET 512, STI regions 504, and DTI regions 510 can be fabricated in the CMOS wafer 502, as described in FIGS. 5A and 5B. In this example, the STI regions 504 can be fabricated prior to the DTI regions 510. In some other embodiments, the DTI regions 608 can be formed before the STI regions 610, as described on FIGS. 6A and 6B.

The method 800 also includes forming a dedicated tap cell in each of the well regions of the CMOS wafer, the dedicated tap cell being connected to corresponding semiconductor well and having a higher doping level than the semiconductor well, at 804. For example, the TAP cell 212 can be formed on the frontside surface of the CMOS device 200a and connected to the well region 202 to prevent latch-up risk. The TAP cell 212 may have a higher doping level to that of the well region 202.

The method 800 further includes forming a dedicated substrate bias contact in each of the well regions of the CMOS wafer, the dedicated substrate bias contact being connected to the semiconductor well to provide biased voltages, at 806. For example, dedicated substrate bias contacts can be formed above the P-well region 102 and the N-well region 104, respectively on the CMOS device 100a. Each of the substrate bias contacts may be connected to a bias voltage source to control a depletion region and a threshold voltage of the FETs on the CMOS device 100a.

In addition, the method 800 includes thinning the CMOS wafer from its backside to expose the plurality of DTI regions extending to a backside surface of the thinned CMOS device, wherein each of the plurality of DTI regions completely surrounds a corresponding well to electrically isolate components included in the well from other well regions, at 808. For example, after forming the DTI regions 510, the CMOS wafer 502 can be thinned from its backside surface by a mechanical grinding or a polishing process. The thinning process continues until the DTI regions 510 expose on the backside surface of the CMOS wafer 502. As described on FIG. 5C, the well region in which the FET 512 is disposed is completely surrounded by the DTI region 510, after the thinning process of the CMOS wafer 502.

Moreover, the method 800 includes depositing a first dielectric layer on the backside surface of the thinned CMOS wafer and a second dielectric layer on a frontside surface of a secondary wafer, at 810. For example, the first dielectric layer and the secondary dielectric layer can be respectively deposited on the backside surface of thinned CMOS wafer 502 and the frontside surface of the secondary wafer 520.

Lastly, the method 800 includes bonding the thinned CMOS wafer to a secondary wafer by forming dielectric-dielectric bonds between the first and second dielectric layers, at 812. For example, the thinned CMOS wafer 502 and secondary wafer 520 can be bonded by aligning the first and second dielectric layers and applying pressure and heat thereon. The dielectric layer 516 including fusion dielectric-dielectric bonds is formed at the interface of CMOS wafer 502 and secondary wafer 520.

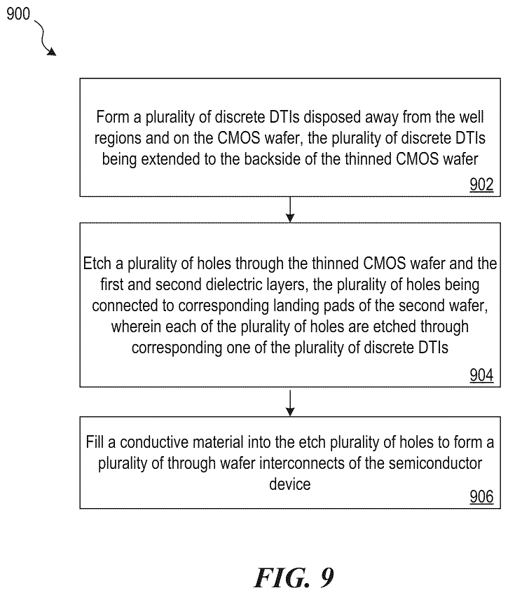

Turning to FIG. 9 which is a flow chart illustrating a method 900 of processing through wafer interconnects of a semiconductor device, in accordance with embodiments of the present technology. The method 900 includes forming a plurality of discrete DTIs disposed away from the well regions and on the CMOS wafer, the plurality of discrete DTIs being extended to the backside of the thinned CMOS wafer, at 902. For example, the additional DTI regions 226 can be formed away from the well regions 202 and in the CMOS device 200a. A shown in FIG. 4A, each of the additional DTI regions 226 can be disposed below corresponding STI regions 218 and extends to the backside surface of the CMOS device 200a.

The method 900 also includes etching a plurality of holes through the thinned CMOS wafer and the first and second dielectric layers, the plurality of holes being connected to corresponding landing pads of the second wafer, wherein each of the plurality of holes are etched through corresponding one of the plurality of discrete DTIs, at 904. For example, through holes can be etched through corresponding STI regions 218, DTI regions 226, and the dielectric layer 216, and in contact to corresponding landing pads of the secondary device 200b.

Lastly, the method 900 includes filling a conductive material into the etch plurality of holes to form a plurality of through wafer interconnects of the semiconductor device, at 906. For example, similar to the formation of through wafer interconnects described on FIG. 5D, the through holes of semiconductor device 200 can be filled by conductive metals or metal alloys to form the through wafer interconnects 222, as shown on FIGS. 4A and 4B.

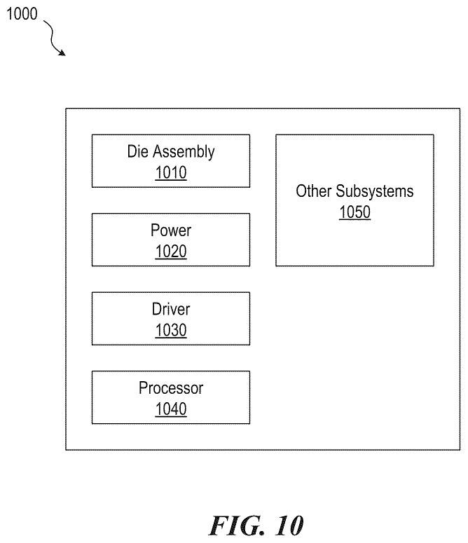

Any one of the semiconductor structures described above with reference to FIGS. 1-9 can be incorporated into any of a myriad of larger and/or more complex systems, a representative example of which is system 1000 shown schematically in FIG. 10. The system 1000 can include a semiconductor device 1010, a power source 1020, a driver 1030, a processor 1040, and/or other subsystems or components 1050. The semiconductor device 1010 can include features generally similar to those of the semiconductor devices described above and can therefore include DTI regions described in the present technology. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, and appliances. Components of the system 1000 may be housed in a single unit or distributed over multiple, interconnected units (e.g., through a communications network). The components of the system 1000 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a complementary metal-oxide-semiconductor (CMOS) device, the CMOS device including:
a P-Well region including a P-Well, a first shallow trench isolation (STI) region that is disposed on a frontside surface of the CMOS device and above the P-Well, and a first deep trench isolation (DTI) region that is disposed under the first STI region and that extends to a backside surface of the CMOS device, the first DTI region completely surrounding the P-Well, and
a N-Well region adjacent to the P-Well region, the N-Well region including a N-Well, a second STI region that is disposed on the frontside surface of the CMOS device and above the N-Well, and a second DTI region that is disposed under the second STI region and that extends to the backside of the CMOS device, the second DTI region completely surrounding the N-Well; and
a secondary device coupled to the backside of the CMOS device, the CMOS device being bonded to the secondary device.

2. The semiconductor device of claim 1, wherein the P-Well extends to the backside surface of the CMOS device, and the N-Well extends to the backside surface of the CMOS device.

3. The semiconductor device of claim 1, wherein the P-Well region includes one or more n-type Field Effect Transistors (NFETs), a p-type tap (PTAP) cell, and a first substrate bias contact, and the N-Well region includes one or more p-type Field Effect Transistors (PFETs), a n-type tap (NTAP) cell, and a second substrate bias contact.

4. The semiconductor device of claim 3, wherein the one or more NFETs, the PTAP cell, and the first substrate bias contact are disposed on a frontside surface of the CMOS device and are isolated by the first STI region, and wherein the one or more PFETs, the NTAP cell, and the second substrate bias contact are disposed on the frontside surface of the CMOS device and are isolated by the second STI region.

5. The semiconductor device of claim 4, wherein the PTAP cell of the P-Well region has a higher doping level than the P-Well, and wherein the NTAP cell of the N-Well region has a higher doping level than the N-Well.

6. The semiconductor device of claim 1, wherein the CMOS device has a thickness ranging from 0.5 μm to 5 μm, wherein each of the first DTI region and the second DTI region has a width ranging from 1 μm to 10 μm.

7. The semiconductor device of claim 1, wherein the secondary device includes circuitries and/or memory arrays.

8. The semiconductor device of claim 1, further comprises a dielectric layer disposed between the CMOS device and the secondary device.

9. The semiconductor device of claim 8, wherein the CMOS device further includes a plurality of DTIs disposed away from the P-Well region and the N-Well region, the plurality of DTIs being under a third STI region that is disposed on the frontside surface of the CMOS device and extending to the backside of the CMOS device.

10. The semiconductor device of claim 9, further comprises a plurality of through wafer interconnects passing through the third STI region, corresponding plurality of DTIs, and the dielectric layer disposed between the CMOS device and the secondary device, wherein the plurality of through wafer interconnects are connected to corresponding landing pads disposed in the secondary device.

11. A semiconductor device, comprising:
a complementary metal-oxide-semiconductor (CMOS) device having a plurality of well regions, each of the plurality of well regions including:
a semiconductor well,
one or more Field Effect Transistors (FETs) disposed in the semiconductor well,
a tap cell connected to the semiconductor well and having a higher doping level than the semiconductor well,
a substrate bias contact connected to the semiconductor well,
a shallow trench isolation (STI) region disposed on a frontside surface of the CMOS device, and
a deep trench isolation (DTI) region that is disposed under the STI region and that extends to a backside surface of the CMOS device, the DTI region completely surrounding the semiconductor well to electrically isolate the semiconductor well and the one or more FETs from other well regions of the CMOS device; and
a secondary device coupled to the backside of the CMOS device, the secondary device being bonded to the CMOS device.

12. The semiconductor device of claim 11, wherein the DTI region has a thickness ranging from 0.5 μm to 5 μm and a width ranging from 1 μm to 10 μm.

13. The semiconductor device of claim 11, further comprises a dielectric layer disposed between the CMOS device and the secondary device, wherein the CMOS device and the secondary device are bonded by dielectric-dielectric bonding of the dielectric layer.

14. The semiconductor device of claim 13, wherein the CMOS device further includes a plurality of discrete DTIs disposed away from the plurality of well regions, the plurality of discrete DTIs being under another STI region disposed on the frontside surface of the CMOS device and extending to the backside of the CMOS device, wherein the semiconductor device further comprises a plurality of through wafer interconnects passing through the another STI region, corresponding plurality of discrete DTIs, and the dielectric layer disposed between the CMOS device and the secondary device, and wherein the plurality of through wafer interconnects are connected to corresponding landing pads disposed in the secondary device.

15. A method of forming a semiconductor device, comprising:
forming a plurality of Field Effect Transistors (FETs), a plurality of shallow trench isolation (STI) regions, and a plurality of deep trench isolation (DTI) regions in corresponding well regions of a complementary metal-oxide-semiconductor (CMOS) wafer;
thinning the CMOS wafer from its backside to expose the plurality of DTI regions extending to a backside surface of the thinned CMOS device, wherein each of the plurality of DTI regions completely surrounds a corresponding well to electrically isolate components included in the well from other well regions;
depositing a first dielectric layer on the backside surface of the thinned CMOS wafer and a second dielectric layer on a frontside surface of a secondary wafer; and
bonding the thinned CMOS wafer to a secondary wafer by forming dielectric-dielectric bonds between the first and second dielectric layers.

16. The method of claim 15, further comprising:
forming a plurality of discrete DTIs disposed away from the well regions and on the CMOS wafer, the plurality of discrete DTIs being extended to the backside of the thinned CMOS wafer;
etching a plurality of holes through the thinned CMOS wafer and the first and second dielectric layers, the plurality of holes being connected to corresponding landing pads of the second wafer, wherein each of the plurality of holes are etched through corresponding one of the plurality of discrete DTIs; and
filling a conductive material into the etch plurality of holes to form a plurality of through wafer interconnects of the semiconductor device.

17. The method of claim 15, further comprising forming a dedicated tap cell in each of the well regions of the CMOS wafer, the dedicated tap cell being connected to corresponding semiconductor well and having a higher doping level than the semiconductor well; and forming a dedicated substrate bias contact in each of the well regions of the CMOS wafer, the dedicated substrate bias contact being connected to the semiconductor well to provide biased voltages.

18. The method of claim 15, wherein the forming of the plurality of STI regions and the plurality of DTI regions includes:
forming the plurality of STI regions through etching a plurality of shallow trenches on the frontside surface of the CMOS wafer and filling with a first dielectric material,
forming a hard mask layer above the plurality of STI regions and patterning the hard mask layer to expose a portion of the plurality of STI regions,
etching, through the exposed portion of the plurality of STI regions, into a substrate of the CMOS wafer to form a plurality of trenches, and
filling a second dielectric material into the plurality of trenches to form the plurality of DTI regions on the CMOS wafer.

19. The method of claim 15, wherein the forming of the plurality of STI regions and the plurality of DTI regions includes:
forming a hard mask layer above the frontside surface of the CMOS wafer, patterning the hard mask layer, etching a substrate of the CMOS wafer through the patterned hard mask layer, and filling with a first dielectric material to form the plurality of DTI regions,
forming another hard mask layer above the frontside surface of the CMOS wafer and patterning the another hard mask layer to expose the plurality of DTI regions,
etching, through the patterned another hard mask layer, into the substrate of the CMOS wafer to form a plurality of shallow trenches, and
filling a second dielectric material into the plurality of shallow trenches to form the plurality of STI regions on the CMOS wafer.

20. The method of claim 15, wherein the forming of the plurality of STI regions and the plurality of DTI regions includes:
etching a plurality of shallow trenches on a the frontside surface of the CMOS wafer and filling with a first dielectric material to form the plurality of STI regions,
patterning a hard mask layer disposed above a frontside surface of the CMOS wafer to expose a portion of each of the plurality of STI regions,
etching through the portion of each of the plurality of STI regions,
etching, through the etched portion of each of the plurality of STI regions, in a substrate of the CMOS wafer to form a plurality of holes, and
filling a second dielectric material into the plurality of holes to form the plurality of DTI regions.
